(19) United States
(12) Patent Application Publication
(10) Pub. No.: US 2004/0261691 A1
(43) Pub. Date: Dec. 30, 2004

(54) Crystallization apparatus and method

(76) Inventor: Kentaro Doguchi, Tochigi (JP)

Correspondence Address: MORGAN & FINNEGAN, L.L.P., 3 WORLD FINANCIAL CENTER, NEW YORK, NY, 10281-2101, US

(21) Appl. No.: 10/874,454

(22) Filed: Jun. 23, 2004

(30) Foreign Application Priority Data
Jun. 25, 2003 (JP) 2003-180675

(51) Int. Cl. C30B 9/00; C30B 11/00; C30B 17/00; C30B 21/02; C30B 28/06; H01L 21/00; H01L 21/84

(52) U.S. Cl. 117/83; 117/81

(57) ABSTRACT

A crystallization apparatus includes a crucible housing a crystalloid material, which includes a seed crystal housing part for housing a seed crystal that is grown into a single crystal from the material, a support component that is connected with the seed crystal housing part of the crucible to support the crucible, a heater that is arranged in a periphery part of the crucible for heating the crucible, and a cooling component with an adjustable cooling capacity that is arrange inside the support component.

This application claims foreign priority benefits based on Japanese Patent Applications No. 2003-180675, filed on Jun. 25, 2003, which is hereby incorporated by reference herein in its entirety as if fully set forth herein.

### BACKGROUND OF THE INVENTION

The present invention relates generally to a crystallization apparatus and method, and more particularly to a crystallization apparatus and method for calcium fluoride (“CaF₂”) crystal as a material suitable for various optical elements, lenses and an exposure apparatus which uses a short wave range of a vacuum ultraviolet (“VUV”) to a far UV (“FUV”) light.

Recent demands for smaller and thinner-profile electronic devices have increased demands for the mounting of finer semiconductor devices onto these electronic devices. Various proposals have been made to improve the exposure resolution and satisfy this requirement. Shortening the wavelength of an exposure light is one effective solution for improved resolution. Therefore, light sources has recently transitioned from KrF excimer laser (with a wavelength of approximately 248 [nm]) to ArF excimer laser (with a wavelength of approximately 193 [nm]). A F₂ excimer laser (with a wavelength of approximately 157 [nm]) is nearly reduced to practice.

However, most glass materials are unsuitable for light sources with short wavelength due to insufficient transmittance. Quartz glass (“SiO₂”), barely available for the ArF excimer laser's wave range, is unusable in the F₂ laser's wave range. For high light transmittance (i.e., internal transmittance) in the above wavelength range, calcium fluoride (“CaF₂”) single crystal is the most suitable optical material for optical elements such as lenses and diffraction gratings which are used with such an exposure optical system.

Parameters for evaluating optical materials such as lenses involve internal transmittance, laser durability indicative of a change in transmittance in response to continuous laser irradiations, refractive index homogeneity indicative of the degree of uniformity of a lens's refractive index depending upon positions, birefringence, workability or grinding performance, etc. CaF₂ crystal used for an exposure apparatus should possess high qualities in these aspects.

A method called the Vertical Bridgman (VB) method (also known as “crucible descent method”) are disclosed in U.S. Pat. No. 2,149,076 and U.S. Pat. No. 2,214,976, for the manufacturing process of the calcium fluoride single crystal. The crystals are grown by moving a crucible in a furnace with a temperature distribution. Another method called the Vertical Gradient Freezing (VGF) method is disclosed in the crystallization handbook (Kyoritsu Publication Co., Ltd.). In that handbook, the temperature distribution changes while the crucible is fixed and the crystal's growth interface moves.

FIG. 8 is a typical sectional view of a conventional crystallization apparatus for the Vertical Gradient Freezing method. The crystallization apparatus 1000 is composed mainly of a housing 1200 that forms a furnace chamber 1100, a side insulator 1300 arranged in the furnace chamber 1100, a side heater 1400 arranged in multistep to precisely control the temperature in the furnace chamber 1100 and a crucible 1500 that houses a material 1600.

During the crystallization process, the crystallization apparatus 1000 maintains the furnace chamber 1100 at reduced pressure or vacuum, and the side heater 1400 heats the material 1600 at a temperature above the melting point of between 1390 [° C.] and 1450 [° C.] to melt the material 1600. It is crystallized from a lower side so that the growth interface moves at a speed of about 0.1 [mm] to 5 [mm] per one hour while the output of the side heater 1400 is adjusted.

However, conventional crystallization apparatuses cannot manufacture a crystal that has high-quality optical characteristics. It is thus necessary to prevent manufacture of a polycrystal and to adjust a starting point of the crystal growth to one point in the crucible to manufacture a high-quality crystal. The conventional VGF method gradually drops the output of the heater arranged in a side of the furnace chamber when the temperature of the furnace chamber is lowered. As a result, it is very difficult to adjust a starting point of the crystal growth to one point because heat that runs away from the side of the crucible increases with the decrease of the output from the heater.

Moreover, when heat that runs away from the side of the crucible increases, the temperature gradient in the crucible becomes small. Thereby, an constitutional supercooling is generated by a segregation of impurities, resulting in an area where the growth speed changes rapidly. Therefore, stable crystal growth cannot be performed and a crystal that has a high-quality optical characteristic cannot be obtained.

### BRIEF SUMMARY OF THE INVENTION

Accordingly, it is an exemplary object of the present invention to provide a crystallization apparatus and method which can stably manufacture crystals having excellent qualities, such as internal transmittance.

A crystallization apparatus of one aspect according to the present invention includes a crucible housing a crystalloid material, which includes a seed crystal housing part for housing a seed crystal that is grown into a single crystal from the material, a support component that is connected with the seed crystal housing part of the crucible to support the crucible, a heater that is arranged in a periphery part of the crucible for heating the crucible, and a cooling component with an adjustable cooling capacity that is arranged inside the support component.

A purification apparatus of another aspect according to the present invention includes a crucible housing a crystalloid material, a support component that is connected with a bottom part of the crucible to support the crucible, a heater that is arranged in a periphery part of the crucible for heating the crucible, and a cooling component with an adjustable cooling capacity that is arrange inside the support component.

A crystallization method of another aspect according to the present invention for growing a single crystal from a crystalloid material, said crystallization method includes the steps of melting the material, and lowering the temperature of the material as the temperature gradient of the material that melts in the melting step is raised.

A purification method of another aspect according to the present invention for purifying a crystalloid material, said purification method includes the steps of melting the material, and lowering a temperature of the material as the temperature gradient of the material that melts in the melting step is raised.

An optical element of another aspect according to the present invention made of a single crystal, the single crystal is manufactured by a crystallization apparatus, wherein the crystallization apparatus includes, a crucible housing a material such as a crystalloid, a seed crystal housing part for housing a seed crystal that is grown into a single crystal from the material, a support component that is connected with the seed crystal housing part of the crucible to support the crucible, a heater that is arranged in a periphery part of the crucible for heating the crucible, and a cooling component with an adjustable cooling capacity that is arranged inside the support component.

An optical element of another aspect according to the present invention made of a single crystal, the single crystal is manufactured by a crystallization method, wherein the crystallization method for growing the single crystal from a crystalloid material, said crystallization method includes the steps of melting the material, and lowering a temperature of the material as the temperature gradient of the material that melts in the melting step is raised.

An exposure apparatus of another aspect according to the present invention which uses ultraviolet radiation, deep ultraviolet radiation, or vacuum ultraviolet radiations as exposure light, for projecting onto an object to be processed through an optical system that includes an optical element made of a single crystal for exposing the object to be processed, wherein the crystallization apparatus for manufacturing the single crystal includes a crucible housing a crystalloid material, a seed crystal housing part for housing a seed crystal that is grown into a single crystal from the material, a support component that is connected with the seed crystal housing part of the crucible to support the crucible, a heater that is arranged in a periphery part of the crucible for heating the crucible, and a cooling component with an adjustable cooling capacity that is arranged inside the support component.

A device fabrication method of another aspect according to the present invention includes the steps of exposing an object using an exposure apparatus, and performing a development process for the object exposed, wherein the exposure apparatus uses ultraviolet radiation, deep ultraviolet radiation, or vacuum ultraviolet radiations as exposure light, for projecting onto the object to be processed through an optical system that includes an optical element made of a single crystal for exposing the object to be processed, wherein the crystallization apparatus for manufacturing the single crystal includes a crucible housing a crystalloid material, a seed crystal housing part for housing a seed crystal that is grown into the single crystal from the material, a support component that is connected with the seed crystal housing part of the crucible to support the crucible, a heater that is arranged in a periphery part of the crucible for heating the crucible, and a cooling component with an adjustable cooling capacity that is arranged inside the support component.

Other objects and further features of the present invention will become readily apparent from the following description of the preferred embodiments with reference to the accompanying drawings.

### BRIEF DESCRIPTION OF THE DRAWINGS

FIG. 1 is a typical sectional view of a crystallization apparatus of the first embodiment according to the present invention.

FIG. 2 is a schematic perspective view showing a cooling component shown in FIG. 1.

FIG. 3 is a graph that exhibits a temperature gradient change of the sidewall of a crucible when the temperature is lowered (crystal growth) by moving the cooling component in the crystallization apparatus of the present invention.

FIG. 4 is a typical sectional view of a crystallization apparatus of the second embodiment according to the present invention.

FIG. 5 is schematic sectional view of an exposure apparatus as one aspect according to the present invention.

FIG. 6 is a flowchart for explaining how to fabricate devices (such as semiconductor chips such as ICs, LCDs, CCDs, and the like).

FIG. 7 is a detailed flowchart of a wafer process in Step 4 of FIG. 6.

FIG. 8 is a typical sectional view of a conventional crystallization apparatus of the Vertical Gradient Freezing method.

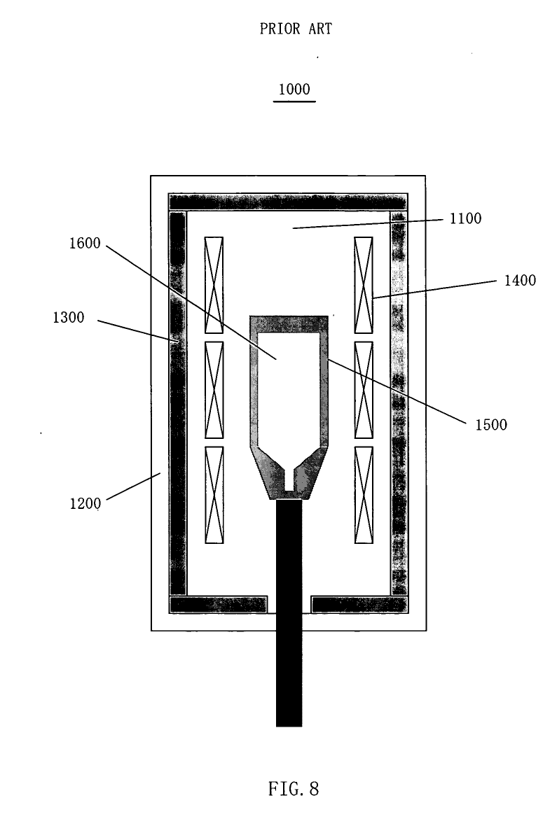

### DETAILED DESCRIPTION OF THE PREFERRED EMBODIMENTS

With reference to the accompanying drawings, a description will be given of a crystallization apparatus of one embodiment according to the present invention. In each figure, the same reference numeral denotes the same element. Therefore, duplicate descriptions will be omitted.

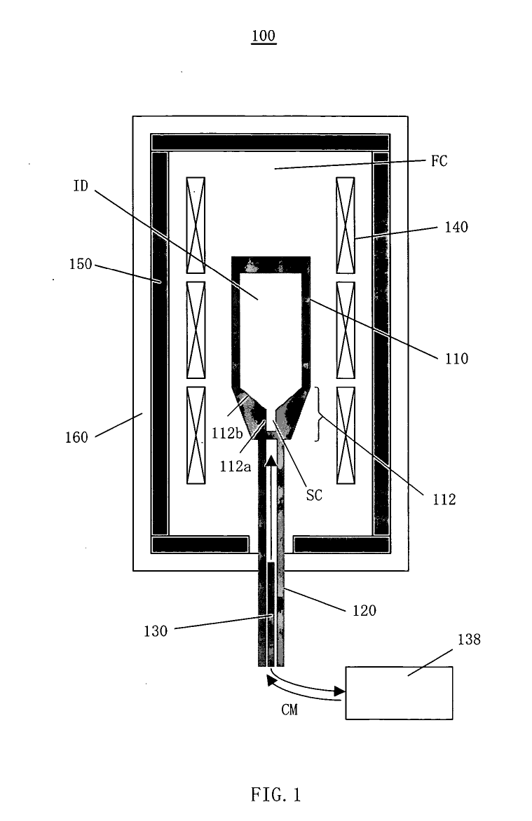

FIG. 1 is the first embodiment of the crystallization apparatus 100 that shows most features of the present invention. The crystallization apparatus 100 melts a material ID in a crucible 110 and then grows crystal of the material ID by cooling.

The crystallization apparatus 100 include a crucible 110 that has an almost cylindrical crucible shape, a support component 120 that supports the crucible 110, a furnace chamber FC that defines a housing 160 that has an almost cylindrical crucible shape for housing the crucible 110 and an insulator 150, and a heater 140 that is arranged according to a periphery part of a cylinder of the crucible 110 for heating the crucible 110. The crystallization apparatus 100 further includes an exhaust apparatus (not shown) that maintains the furnace chamber FC at reduced pressure or vacuum.

The crucible 110 has a lid that freely opens and shuts, and a bottom part 112 that starts the crystal growth in the crucible 110 has a convex below shape for the outside side section and inside side section shape. The crucible 110 houses the material ID as a crystalloid (the instant embodiment uses calcium fluoride). The crucible 110 is made of a material that does not react with the melted crystalloid and have few impurities, such as, carbon, platinum, silica glass and boron nitride, because the crucible 110 contains the melted crystalloid and crystal grows from the crystalloid material ID.

When the crucible 110 is selected, it is desirable that the heat conductivity level of the crucible 110 is equal to the heat conductivity of the grown crystal (especially, ½-2 times). When the heat conductivity is too large, the heat conductivity in the vertical direction of the crucible 110 and the temperature gradient in the vertical direction of the crystal growth becomes small. On the other hand, when the heat conductivity is too small, it is difficult to diffuse the temperature distribution formed by the heater in the crystal because of the crucible's heat insulation effect, and forming the temperature gradient in a prescribed vertical direction to the crystal growth becomes difficult.

The crucible 110 houses a seed crystal SC in the seed crystal housing part 112a of the tapered bottom part 112. A tapered bottom part 112 formed in the housing part 112a is to be coupled with the inside of the crucible 110. A growth area of the seed crystal SC set up in the seed crystal housing part 112a increases according to growth. Setting up a desired crystal orientation of the seed crystal SC (in other words, the single crystal used as seed when a large single crystal that has a certain crystal orientation is grown) in the seed crystal housing part 112a for a vertical growth direction growth can control a grown crystal's orientation. The crucible 110, connected with the support component 120 in the seed crystal housing part 112a of the bottom part 112 of the crucible 110, is arranged at a center part of the furnace chamber FC.

The support component 120 penetrates through a bottom part of the housing 160, and an upper part reaches the furnace chamber FC. The support component 120 supports the crucible 110 and weight of the melted crystalloid in the crucible 110. The support component 120, driven by a rotation mechanism (not shown), is also designed to rotate the crucible 110. The rotation by the support component 120 makes the temperature of the crucible 110 uniform. A cooling component 130 is attached to a driving mechanism that is different from the crucible's up-and-down moving mechanism so that it is movable in the vertical direction (in other words, the growth direction of the crystal), is inserted inside the support component 120.

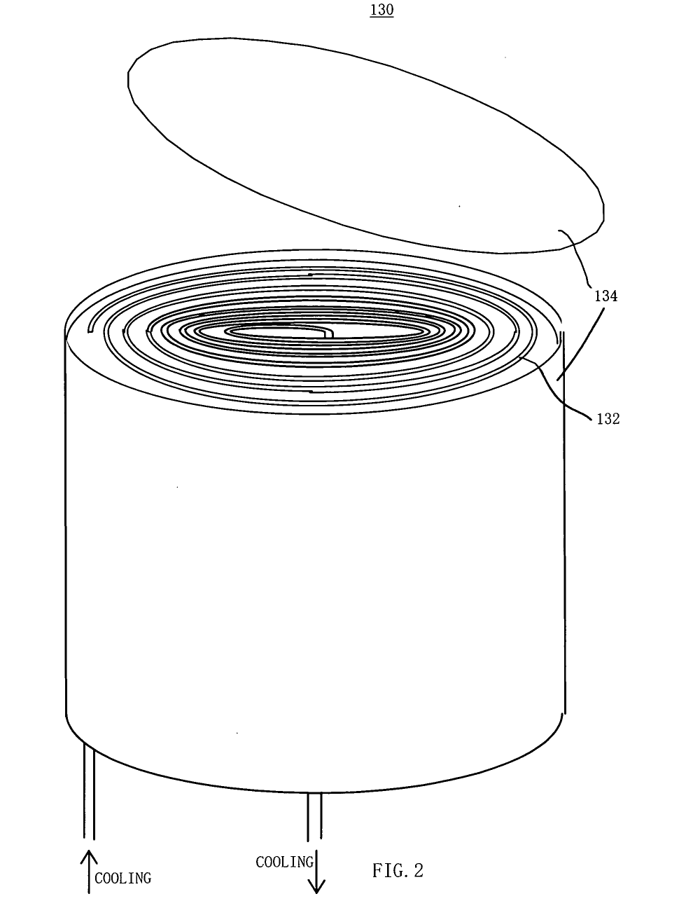

The cooling component 130 is arranged in the inside of the support component 120. In FIG. 1, the sides of the cooling component 130 and the support component 120 are detached, but may contact. The cooling component 130 has a double pipe structure 132 as shown in FIG. 2. Here, FIG. 2 is a schematic perspective view showing the cooling component 130 shown in FIG. 1.

With reference to FIG. 2, the cooling component 130 is a metallic double pipe rolled like a spiral (in other words, the double pipe structure 132) and covered with a carbon case 134. Because it is designed like this, the cooling component 130 is not corroded by the hydrogen fluoride generated while the crystal of calcium fluoride is grown. Additionally, a uniform cooling plane can be formed by using high heat conductivity possessed by the carbon.

A cooling medium CM flows through the double pipe structure 132. With a temperature adjusting mechanism 138, the cooling capacity of the cooling component 130 can be adjusted by changing the flow rate and temperature of the cooling medium CM that flows through the double pipe structure 132. The cooling medium CM uses, for example, water or gases such as argon and nitrogen (low temperature gas).

When the crystalloid material ID melts, the cooling component 130 is lowered, and then when the crystal grows, the cooling component 130 gradually moves in the direction of the crucible 110. As a result, it is possible to cool from one point of the crucible's 110 bottom part 112 (in other words, the seed crystal housing part 112a). At this time, it is possible to precisely grow crystals by adjusting the temperature of the cooling medium CM of water, gas, etc. with the temperature adjusting mechanism 138 as mentioned above and moving the cooling medium 130 at the same time. Therefore, the crystallization apparatus 100 can lower the inside temperature of the crucible 110 without dropping the output of the heater 140 on the side. It can also prevent the temperature gradient in the crucible 110 from becoming small.

In other words, if it is necessary to maintain a lower side of the crucible 110 at a comparatively high temperature to keep the temperature gradient of a crystal's growth part (interface of solid and liquid phases) at a predetermined level during the initial growth of the crystal, as shown in FIG. 1, the cooling component 130 is arranged away from the crucible 110 and the cooling capacity is kept low. Moreover, it is necessary to decrease the temperature of the lower side of the crucible 110 to maintain the temperature gradient of the growth part of the crystal, which is predetermined according to the growth part of the crystal as it goes away from the lower side of the crucible 110 and the growth of the crystal advances. Therefore, it is effective to bring the cooling component 130 close to the crucible 110 to improve the cooling capacity. In addition to adjustments mentioned above, the temperature of the cooling component 130 is adjusted by adjusting the distance between the cooling component 130 and the crucible 110. Moreover, the desired temperature of the lower side of the crucible 110 can be maintained through a wide temperature range.

The heater 140, arranged like a ring around the crucible 110, heats and melts the material ID in each crucible 110. The heater 140 of the instant embodiment heats the crucible 110 along a perpendicular direction of the crucible 110 with uniform heat power. The heater 140 uses a multistep to precisely control the temperature of the furnace chamber FC.

The insulator 150 inside the furnace chamber FC is arranged around the heater 140. The insulator 150 is made of carbon that is polished on the inside. The insulator 150 protects the inside of the housing 160 from the heat of the heater 140.

The housing 160 blocks the atmosphere of the furnace chamber FC from the outside when the crystal grows, and maintains the furnace chamber FC at reduced pressure or vacuum. In the instant embodiment, the housing 160 is composed of a double cylinder made of stainless steel and an arrangement of insulator (not shown) in the double cylinder.

The calcium fluoride with a thickness of about 50 [mm] was manufactured by using the crystallization apparatus 100 shown in FIG. 1. The calcium fluoride used for the material ID is not rough (natural fluorite), instead a ground product of high-purity calcium fluoride, which was processed by chemically synthesizing CaCO₃ with hydrogen fluoride, was then melted and re-solidified (in other words, purification). This is because high-purity calcium fluoride which is large decreases in volume when melted. Therefore, the size of the crystal obtained in comparison to the size of the crucible 110 is remarkably small. The seed crystal SC of calcium fluoride was set in the seed crystal housing part 112a, the crucible 110 was filled with ground material ID, and the furnace chamber FC was maintained to a vacuum level of about 10⁻³ [Pa]−10⁻⁴ [Pa] by operating the exhaust apparatus (not shown).

Next, the heater 140 heats the furnace chamber FC so that the seed crystal SC is about 1350 [° C.] which is below the melting point of calcium fluoride and the material ID of calcium fluoride other than the seed crystal SC is about 1450 [° C.] which is more than the melting point of the calcium fluoride. This state was maintained until the temperature gradient of the furnace chamber FC, including the material ID of calcium fluoride, became steady.

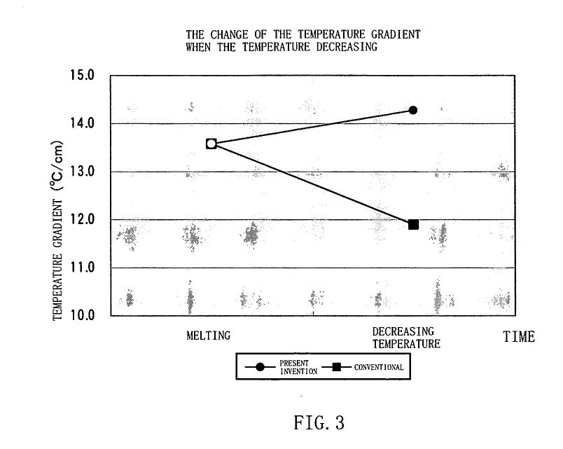

Afterward, the cooling component 130 was raised from a position 500 [mm] under the crucible 110 (the melting temperature of the material ID) to a position 5 [mm] near the crucible 110. With the output of the heater 140 maintained there was gradual crystallization from the bottom part 112 of the crucible 110. FIG. 3 is the graph that exhibits a change of the temperature gradient of the crucible's 110 sidewall when the temperature is lowered (crystal growth) by moving the cooling component 130 in the crystallization apparatus 100 of the present invention. FIG. 3 uses the temperature gradient [° C./cm] for the ordinate axis and the time for the abscissa axis. Moreover, as a conventional example, a plot of the temperature gradient change was made for the temperature of the crucible 110 when the heater output was dropped 20% from the melting state.

With reference to FIG. 3, it is understood that the temperature gradient becomes small when the temperature in the conventional example is lowered while the temperature gradient becomes big in the present invention. The graph shown in FIG. 3 is of a crystal manufactured from calcium fluoride with a thickness of about 50 [mm]. Therefore, the temperature gradient becomes much smaller because the amount of temperature decrease increases according to the thickness of the crystal as it becomes thick. Therefore, the effect increases as the thickness of the crystal grows. By adjusting the temperature of the crucible 110 with the cooling component 130 that is arranged on the inside of the support component 120 and moving it so that the temperature gradient may be raised, the crystallization apparatus 100 of the present invention can stably manufacture high-quality single crystal without rapidly changing the growth temperature. The crystallization apparatus 100 can adjust the starting point of the crystal growth to one point because the support component 120 is connected to the seed crystal housing part 112a at the bottom part 112 of the crucible 110, and the crucible 110 is cooled from the seed crystal housing part 112a by the cooling component 130.

While noting the decrease in temperature because the calcium fluoride crystal breaks when rapidly cooled, the calcium fluoride crystal that was grown was returned to room temperature. Because the calcium fluoride crystal of this state has big residual stress and distortion, heat treatment (anneal) processing is required.

Thus, an optical element made from calcium fluoride crystal is obtained from the inventive crystallization apparatus 100. The optical element may include, for example, a lens, a diffraction optical element, an optical film, and a combination thereof. For example, it may include a lens, a multi-lens, a lens array, a lenticule lens, a fly-eye lens, an aspheric lens, a diffraction grating, a binary optics element and any combination thereof. The optical element include, for example, an optical sensor (e.g., for use with focus control) in addition to a single lens. If necessary, an anti-reflection coating may be provided on the optical element made from calcium fluoride crystal. The anti-reflection coating is suitably made, for example, of magnesium fluoride, aluminum oxide, and tantalum oxide, by resistance heating vapor deposition, electron beam vapor deposition, sputtering, etc. The optical element obtained by the present invention has excellent qualities, such as internal transmittance and laser durability, and thus exhibits more improved optical performance than the conventional optical elements.

A projection optical system and an illumination optical system suitable for ArF excimer laser and F₂ laser can be made of a combination of various inventive optical elements. An exposure apparatus for photolithography can include a laser light source, an optical system that includes calcium fluoride lens(es) obtained from the inventive crystallization apparatus 100, and a stage for driving a wafer.

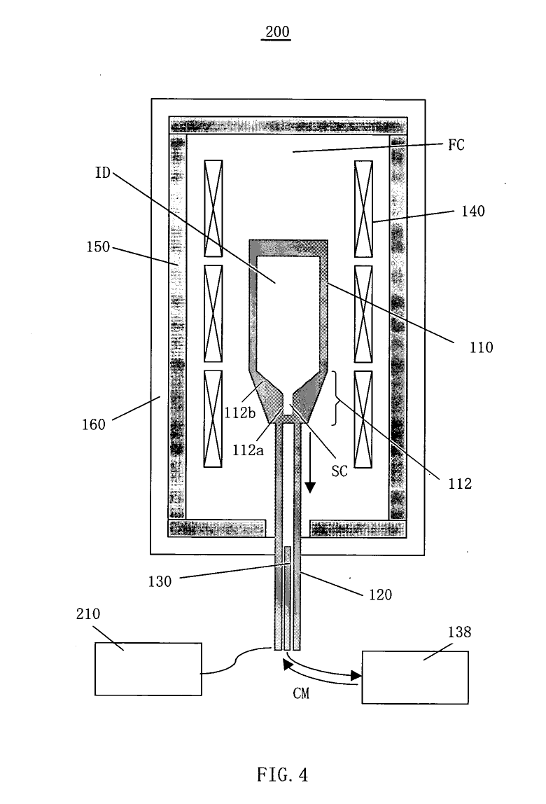

FIG. 4 is a typical sectional view of a crystallization apparatus 200 of the second embodiment according to the present invention. With reference to FIG. 4, the crystallization apparatus 200 is the same as the crystallization apparatus 100 shown in FIG. 1 where the basic composition has a cooling component 130 arranged inside the support component 120. The crystallization apparatus 200 further includes a crucible moving mechanism 210. Moreover, in FIG. 4, the sides of the cooling component 130 and the support component 120 are detached, but may contact.

When the crystalloid material ID melts, the crucible 110 is raised. Then, when the crystal is grown or purified, the crucible 110 gradually moves in a direction of the cooling component 130. As a result, it is possible to cool from one point of the bottom part 112 of the crucible 110 (in other words, the seed crystal housing part 112a). Therefore, the crystallization apparatus 200 can lower the temperature of the inside of the crucible 110 without dropping the output of the heater 140 on the side, and can prevent the temperature gradient in the crucible 110 from becoming small.

Thus, the crystallization apparatus 100 and 200 can grow the crystal while maintaining a high temperature gradient for the inside of the crucible 110 by controlling the temperature of the crucible 110 through the use of the cooling component 130 arranged on the inside of the support component 120. As a result, the growth speed and the growth starting point of the crystal are steady. Therefore, the crystallization apparatus 100 and 200 can manufacture crystals having excellent qualities, such as internal transmittance and laser durability.

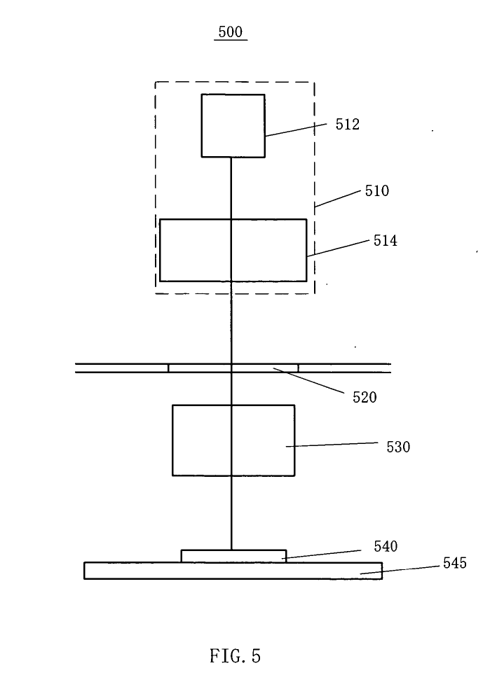

Referring now to FIG. 5, a description will be given of the exposure apparatus 500. Here, FIG. 5 is a schematic sectional view of the exposure apparatus 500 as one aspect according to the present invention. The exposure apparatus 500 includes, as shown in FIG. 5, an illumination apparatus 510 for illuminating a reticle 520 which forms a circuit pattern, a projection optical system 530 that projects diffracted light created from the illuminated reticle pattern onto a plate 540, and a stage 545 for supporting the plate 540.

The exposure apparatus 500 is a projection exposure apparatus that exposes onto the plate 540 a circuit pattern created on the reticle 520, e.g., in a step-and-repeat or a step-and-scan manner. Such an exposure apparatus is suitable for a sub-micron or quarter-micron lithography process. This embodiment exemplarily describes a step-and-scan exposure apparatus (which is also called “a scanner”). The “step-and-scan manner”, as used herein, is an exposure method that exposes a reticle pattern onto a wafer by continuously scanning the wafer relative to the reticle, and by moving, after an exposure shot, the wafer stepwise to the next exposure area to be shot. The “step-and-repeat manner” is another mode of exposure method that moves a wafer stepwise to an exposure area for the next shot, for every cell projection shot.

The illumination apparatus 510 which illuminates the reticle 520 that forms a circuit pattern to be transferred, includes a light source unit 512 and an illumination optical system 514.

As an example, the light source unit 512 uses a light source such as ArF excimer laser with a wavelength of approximately 193 [nm] and KrF excimer laser with a wavelength of approximately 248 [nm]. However, the laser type is not limited to excimer lasers because for example, F₂ laser with a wavelength of approximately 157 [nm] and a YAG laser may be used. Similarly, the number of laser units is not limited. For example, two independently acting solid lasers would cause no coherence between these solid lasers and significantly reduces speckles resulting from the coherence. An optical system for reducing speckles may swing linearly or rotationally. When the light source unit 512 uses laser, it is desirable to employ a beam shaping optical system that shapes a parallel beam from a laser source to a desired beam shape, and an incoherently turning optical system that turns a coherent laser beam into an incoherent one. A light source applicable for the light source unit 512 is not limited to a laser, and may use one or more lamps such as a mercury lamp and a xenon lamp.

The illumination optical system 514 is an optical system that illuminates the reticle 520, and includes a lens, a mirror, a light integrator, a stop, and the like, for example, a condenser lens, a fly-eye lens, an aperture stop, a condenser lens, a slit, and an image-forming optical system in this order. The illumination optical system 514 can use any light regardless of whether it is axial or non-axial light. The light integrator may include a fly-eye lens or an integrator formed by stacking two sets of cylindrical lens array plates (or lenticular lenses), and can be replaced with an optical rod or a diffractive element. The inventive calcium fluoride crystal is applicable to optical elements, such as, a lens in the illumination optical system 514.

The reticle 520 is made, for example, of quartz, forms a circuit pattern (or an image) to be transferred, and is supported and driven by a mask stage (not shown). Diffracted light emitted from the reticle 520 passes through the projection optical system 530 and is then projected onto the plate 540. The reticle 520 and the plate 540 are located in an optically conjugate relationship. Since the exposure apparatus 500 of this embodiment is a scanner, the reticle 520 and the plate 540 are scanned at the speed ratio of the reduction ratio of the projection optical system 530, thus transferring the pattern from the reticle 520 to the plate 540. If it is a step-and-repeat exposure apparatus (referred to as a “stepper”), the reticle 520 and the plate 540 remains still when exposing the mask pattern.

The projection optical system 530 is an optical system that projects light that reflects a pattern on the reticle 520 located on an object surface onto the plate 540 located on an image surface. The projection optical system 530 may use an optical system comprising solely of a plurality of lens elements, an optical system including a plurality of lens elements and at least one concave mirror (a catadioptric optical system), an optical system including a plurality of lens elements and at least one diffractive optical element such as a kinoform, a full mirror type optical system, and so on. Any necessary correction of the chromatic aberration may be accomplished by using a plurality of lens units made from glass materials having different dispersion values (Abbe values) or arranging a diffractive optical element such that it disperses light in a direction opposite to that of the lens unit. An optical element made of the inventive calcium fluoride crystal is applicable to any optical element, such as a lens in the projection optical system 530.

The plate 540, such as a wafer and a LCD, is an exemplary object to be exposed. Photoresist is applied to the plate 540. A photoresist application step includes a pretreatment, an adhesion accelerator application treatment, a photo-resist application treatment, and a pre-bake treatment. The pretreatment includes cleaning, drying, etc. The adhesion accelerator application treatment is a surface reforming process to enhance the adhesion between the photoresist and a base (i.e., a process to increase the hydrophobicity by applying a surface active agent), through a coat or vaporous process using an organic coating such as HMDS (Hexamethyl-disilazane). The pre-bake treatment is a baking (or burning) step, which makes the photoresist softer than after development and removes the solvent.

The stage 545 supports the plate 540. The stage 545 may use any structure known in the art, thus, a detailed description of its structure and operation is omitted. The stage 545 may use, for example, a linear motor to move the plate 540 in the XY directions. The reticle 520 and plate 540 are, for example, scanned synchronously, and the positions of the stage 545 and a mask stage (not shown) are monitored, for example, by a laser interferometer and the like, so that both are driven at a constant speed ratio. The stage 545 is installed on a stage stool supported on the floor and the like, for example, via a dampener. The mask stage and the projection optical system 530 are installed on a lens barrel stool (not shown) support, for example, via a dampener, to the base frame placed on the floor.

In exposure, light is emitted from the light source 512, e.g., Koehler-illuminates the reticle 520 via the illumination optical system 514. Light that passes through the reticle 520 and reflects the mask pattern is imaged onto the plate 540 by the projection optical system 530. The illumination and projection optical systems 514 and 530 in the exposure apparatus 500 include an optical element made of inventive calcium fluoride crystal that transmits the UV light, FUV light, and VUV light with high transmittance, and provide high-quality devices (such as semiconductor devices, LCD devices, photographing devices (such as CCDs, etc.), thin film magnetic heads, and the like) with high throughput and economic efficiency.

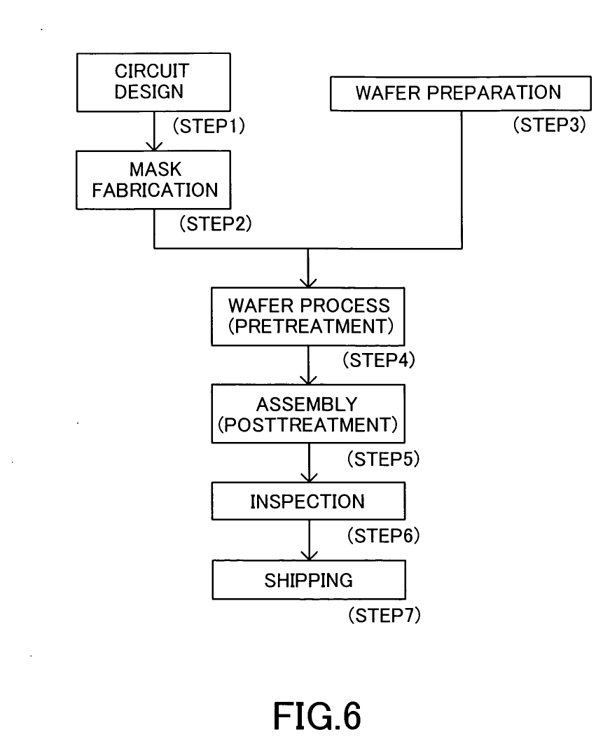

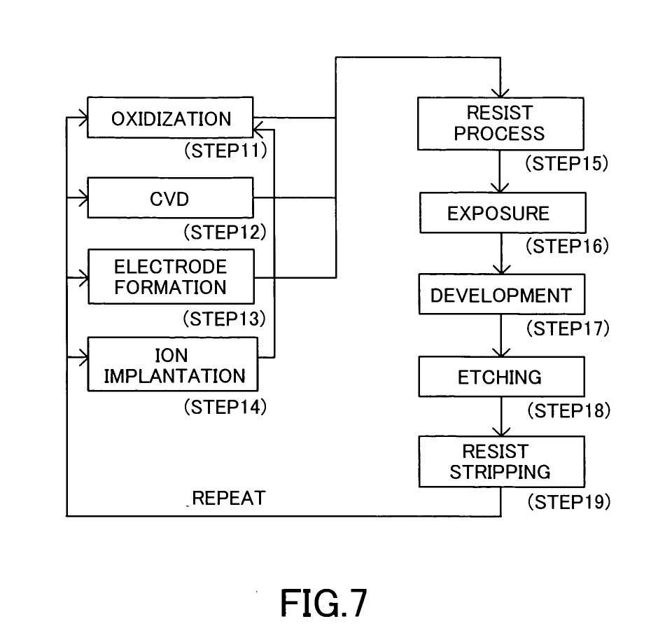

Referring now to FIGS. 6 and 7, a description will be given of an embodiment of a device fabrication method using the above mentioned exposure apparatus 500. FIG. 6 is a flowchart for explaining how to fabricate devices (i.e., semiconductor chips such as IC and LSI, LCDs, CCDs, and the like). Here, a description will be given of the fabrication of a semiconductor chip as an example. Step 1 (circuit design) designs a semiconductor device circuit. Step 2 (mask fabrication) forms a mask having a designed circuit pattern. Step 3 (wafer making) manufactures a wafer using materials such as silicon. Step 4 (wafer process), which is also referred to as a pretreatment, forms the actual circuitry on the wafer through lithography using the mask and wafer. Step 5 (assembly), which is also referred to as a post-treatment, forms into a semiconductor chip the wafer formed in Step 4 and includes an assembly step (e.g., dicing, bonding), a packaging step (chip sealing), and the like. Step 6 (inspection) performs various tests on the semiconductor device made in Step 5, such as a validity test and a durability test. Through these steps, a semiconductor device is finished and shipped (Step 7).

FIG. 7 is a detailed flowchart of the wafer process in Step 4. Step 11 (oxidation) oxidizes the wafer's surface. Step 12 (CVD) forms an insulating layer on the wafer's surface. Step 13 (electrode formation) forms electrodes on the wafer by vapor disposition and the like. Step 14 (ion implantation) implants ion into the wafer. Step 15 (resist process) applies a photosensitive material onto the wafer. Step 16 (exposure) uses the exposure apparatus 500 to expose a circuit pattern from the mask onto the wafer. Step 17 (development) develops the exposed wafer. Step 18 (etching) etches parts other than a developed resist image. Step 19 (resist stripping) removes unused resist after etching. These steps are repeated to form multi-layer circuit patterns on the wafer. Use of the fabrication method in this embodiment helps fabricate higher-quality devices than conventional methods. Thus, the device fabrication method using the exposure apparatus 500, and resultant devices constitute one aspect of the present invention.

Furthermore, the present invention is not limited to these preferred embodiments and various variations and modifications may be made without departing from the scope of the present invention. For example, the crystallization apparatus of the present invention can also be applied to a purification apparatus that purifies a crystalloid material.

Thus, the present invention provides a crystallization apparatus, which can stably manufacture crystals having excellent qualities, such as internal transmittance and laser durability.

1. A crystallization apparatus comprising:
a crucible housing a crystalloid material, which includes a seed crystal housing part for housing a seed crystal that is grown into a single crystal from the material;
a support component that is connected with the seed crystal housing part of the crucible to support the crucible;
a heater arranged in a periphery part of the crucible for heating the crucible; and
a cooling component with an adjustable cooling capacity that is arrange inside the support component.

2. A crystallization apparatus according to claim 1, wherein the relative positional relationship of the crucible and the cooling component are changeable.

3. A crystallization apparatus according to claim 1, wherein the cooling component is movable inside the support component.

4. A crystallization apparatus according to claim 1, further comprising a crucible moving mechanism that moves the crucible.

5. A crystallization apparatus according to claim 1, wherein the cooling component includes a double pipe structure for a cooling medium to flow through.

6. A crystallization apparatus according to claim 5, wherein the cooling medium is water or gas.

7. A crystallization apparatus according to claim 5, further comprising a temperature adjustment mechanism for adjusting a temperature of the cooling medium.

8. A crystallization apparatus according to claim 1, wherein the material is calcium fluoride.

9. A purification apparatus comprising:
a crucible housing a crystalloid material;
a support component that is connected with a bottom part of the crucible to support the crucible;
a heater that is arranged in a periphery part of the crucible, for heating the crucible; and
a cooling component with an adjustable cooling capacity that is arrange inside the support component.

10. A crystallization method for growing a single crystal from a crystalloid material, said crystallization method comprising the steps of:
melting the material; and
lowering a temperature of the material as a temperature gradient of the material that melts in the melting step is raised.

11. A purification method for purifying a crystalloid material, said purification method comprising the steps of:
melting the material; and
lowering a temperature of the material as a temperature gradient of the material that melts in the melting step is raised.

12. An optical element made of a single crystal, the single crystal being manufactured by a crystallization apparatus,
wherein the crystallization apparatus includes:
a crucible housing a crystalloid material, which includes a seed crystal housing part for housing a seed crystal that is grown into a single crystal from the material,
a support component that is connected with the seed crystal housing part of the crucible to support the crucible,
a heater that is arranged in a periphery part of the crucible for heating the crucible; and
a cooling component with an adjustable cooling capacity that is arrange inside the support component.

13. An optical element made of a single crystal, the single crystal being manufactured by a crystallization method,
wherein the crystallization method for growing the single crystal from a crystalloid material, said crystallization method includes the steps of:
melting the material; and
lowering a temperature of the material as a temperature gradient of the material that melts in the melting step is raised.

14. An optical element according to claim 12, wherein the optical element is a lens, a diffraction grating, an optical film or combination thereof.

15. An exposure apparatus that uses ultraviolet radiation, deep ultraviolet radiation, or vacuum ultraviolet radiations as exposure light, which is projected onto an object to be processed through a optical system that includes an optical element made of a single crystal to expose the object to be processed,
wherein the single crystal being manufactured by a crystallization apparatus includes a crucible housing a crystalloid material, and includes:
a seed crystal housing part for housing a seed crystal that is grown into the single crystal from the material;
a support component that is connected with the seed crystal housing part of the crucible to support the crucible;
a heater that is arranged in a periphery part of the crucible for heating the crucible; and
a cooling component with an adjustable cooling capacity that is arrange in an inside the support component.

16. A device fabrication method comprising the steps of:
exposing an object using an exposure apparatus; and
performing a development process for the object exposed,
wherein the exposure apparatus uses ultraviolet radiation, deep ultraviolet radiation, or vacuum ultraviolet radiations as exposure light, which is projected onto the object to be processed through a optical system that includes an optical element made of a single crystal to expose the object to be processed,
wherein the single crystal being manufactured by a crystallization apparatus includes:
a crucible housing a crystalloid material, which includes a seed crystal housing part for housing a seed crystal that is grown into the single crystal from the material;
a support component that is connected with the seed crystal housing part of the crucible to support the crucible a heater that is arranged in a periphery part of the crucible for heating the crucible; and
a cooling component with an adjustable cooling capacity that is arrange inside the support component.

17. An optical element according to claim 13, wherein the optical element is a lens, a diffraction grating, an optical film or combination thereof.
